(19) United States
(12) Patent Application Publication
(10) Pub. No.: US 2022/0147118 A1
(43) Pub. Date: May 12, 2022

(54) COVERS FOR ELECTRONIC DEVICES

(71) Applicant: Hewlett-Packard Development Company, L.P., Spring, TX (US)

(72) Inventors: Chi Hao Chang, Taipei City (TW); Kuan-Ting Wu, Taipei City (TW); Hui He, Fort Collins, CO (US)

(73) Assignee: Hewlett-Packard Development Company, L.P., Spring, TX (US)

(21) Appl. No.: 17/298,582

(22) PCT Filed: Jul. 25, 2019
(86) PCT No.: PCT/US2019/043487

§ 371 Date: May 30, 2021

(51) Int. Cl. G06F 1/18; C25D 11/26; C25D 11/30; C25D 13/12; H05K 5/02; H05K 5/03

(52) U.S. Cl. CPC G06F 1/181; C25D 11/26; H05K 5/03; C25D 13/12; H05K 5/0243; C25D 11/30

(57) ABSTRACT

The present disclosure is drawn to covers for electronic devices. In one example, a cover for an electronic device can include an enclosure with a light metal substrate with an opening therethrough, and a first protective coating covering the light metal substrate. A second protective coating is on the first protective coating, and a chamfered edge is present along the opening where the chamfer cuts through the first protective coating and the second protective coating to expose the light metal substrate at the chamfered edge. In one example, a transparent passivation layer is included along the chamfered edge.

### BACKGROUND

The use of personal electronic devices of all types continues to increase. Cellular phones, including smartphones, have become nearly ubiquitous. Tablet computers have also become widely used in recent years. Portable laptop computers continue to be used by many for personal, entertainment, and business purposes. For portable electronic devices in particular, much effort has been expended to make these devices more useful and more powerful while at the same time making the devices smaller, lighter, and more durable. The aesthetic design of personal electronic devices is also of concern in this competitive market. Devices such as mobile phones, tablets and portable computers are generally provided with a casing. The casing typically provides a number of functional features, e.g. protecting the device from damage.

### BRIEF DESCRIPTION OF THE DRAWING

FIG. 1 is a cross-sectional view illustrating an example cover for an electronic device in accordance with examples of the present disclosure;

FIG. 2 is a cross-sectional view illustrating another example cover for an electronic device in accordance with examples of the present disclosure;

FIG. 3 is a top down view and a partial cross-sectional view of an example cover for an electronic device in accordance with the present disclosure;

FIG. 4 is a cross-sectional view of an electronic device in accordance with examples of the present disclosure;

FIG. 5 is a flowchart illustrating an example method of making a cover for an electronic device in accordance with examples of the present disclosure; and

FIGS. 6A-6F are cross-sectional views showing another example method of making a cover for an electronic device in accordance with examples of the present disclosure.

### DETAILED DESCRIPTION

The present disclosure describes covers for electronic devices. In one example, a cover for an electronic device includes an enclosure with a light metal substrate having an opening therethrough, a first protective coating covering the light metal substrate, and a second protective coating covering the first protective coating. A chamfered edge is present along the opening, wherein the chamfered edge cuts through the first protective coating and the second protective coating to expose the light metal substrate at the chamfered edge. A transparent passivation layer is included on the light metal substrate along the chamfered edge. In one example, the light metal substrate can be a magnesium alloy that is formed from sheet or forge magnesium alloy using insert molding. The first protective coating can be an opaque passivation layer including molybdates, vanadates, phosphates, chromates, stannates, manganese salts, or a combination thereof. The first protective coating can be a micro-arc oxidation layer. The second protective coating can be a multilayered coating including a primer coat including a polyester, a polyurethane, or a copolymer thereof, and can further include one or both of a base coat or a top coat. The base coat if present can include a polyester, a polyurethane, or a copolymer thereof. The top coat if present can include a polyurethane, a polyacrylic or polyacrylate, a urethane, an epoxy, or a copolymer thereof. The chamfered edge can be formed using a computer numerical control (CNC) mill or laser engraving. The transparent passivation layer can include a pretreatment chemical that includes ethylenediaminetetraacetic acid, ethylenediamine, nitrilotriacetic acid, diethylenetriaminepenta, nitrilotris, hydroxyethane, diphosphonic acid, phosphoric acid, organic acid, or a combination thereof. The cover can further include a second chamfered edge with a second transparent passivation layer. The cover can include an electrophoretic deposition layer covering the transparent passivation layer over the chamfered edge to form a colored layer.

In another example, an electronic device can include an electronic component and a cover enclosing the electronic component. The cover can include an enclosure including a light metal substrate having an opening therethrough, a first protective coating covering the light metal substrate, a second protective coating covering the first protective coating, a chamfered edge along the opening, wherein the chamfered edge cuts through the first protective coating and the second protective coating to expose the light metal substrate at the chamfered edge, and a transparent passivation layer on the light metal enclosure along the chamfered edge. The electronic device can be a laptop housing, a desktop housing, a keyboard housing, a mouse housing, a printer housing, a smartphone housing, a tablet housing, a monitor housing, a television screen housing, a speaker housing, a game console housing, a video player housing, an audio player housing, or a combination thereof. The chamfered edge can be located at an edge of a touchpad, an edge of a fingerprint scanner, or an edge of a logo. The cover can further include multiple chamfered edges with multiple colors at different chamfered edges.

In another example, a method of making a cover for an electronic device includes, for example, forming an enclosure with an opening from a light metal, applying a first protective coating covering the light metal, and applying a second protective coating covering the first protective coating. The method can further include chamfering an edge along the opening to form a chamfered edge, wherein the chamfered edge cuts through the first protective coating and the second protective coating to expose the light metal at the chamfered edge, and can further include applying a transparent passivation layer at the chamfered edge where the light metal is exposed. In one example, the method may include applying an electrophoretic deposition layer covering the transparent passivation layer over the chamfered edge.

It is noted that when discussing the cover, the electronic device, or the method of manufacturing the cover, such discussions of one example are to be considered applicable to the other examples, whether or not they are explicitly discussed in the context of that example. Thus, in discussing a metal alloy in the context of the cover, such disclosure is also relevant to and directly supported in the context of the electronic device, the method of manufacturing the multi-color electronic housing, and vice versa.

### Covers for Electronic Devices

The present disclosure describes covers for electronic devices that can be strong and lightweight and have a decorative appearance. The cover can provide an enclosure for an electronic device and the enclosure can include a light metal substrate. The term “light metal” refers to metals and alloys that are generally any metal of relatively low density including metal that is less than about 5 g/cm³. In some cases, light metal can be a material including aluminum, magnesium, titanium, lithium, zinc, and alloys thereof. These light metals can have useful properties, such as low weight, high strength, and an appealing appearance. However, some of these metals can be easily oxidized at the surface, and may be vulnerable to corrosion or other chemical reactions at the surface. For example, magnesium or magnesium alloys in particular can be used to form covers for electronic devices because of the low weight and high strength of magnesium. Magnesium can have a somewhat porous surface that can be vulnerable to chemical reactions and corrosion at the surface. In some examples, magnesium or magnesium alloy can be treated by micro-arc oxidation to form a layer of protective oxide at the surface. With this example in mind, it is understood that magnesium alloy may be described herein as a class of alloys in some detail by way of example for convenience, but it is also understood that other light metal substrates can be freely substituted for the magnesium alloy examples herein with respect to the covers, electronic devices, and methods herein.

Using magnesium or magnesium alloy as an example class of metal substrates that can be used, this material can form a protective oxide layer that can increase the chemical resistance, hardness, and durability of the magnesium or magnesium alloy. However, micro-arc oxidation can also create a dull appearance instead of the original luster of the metal. In other examples, as an alternative to the MAO the magnesium or magnesium alloy can be treated using a passivation layer. The passivation layer may contain at least one of molybdates, vanadates, phosphates, chromates, stannates and manganese salts.

The present disclosure describes covers for electronic devices that can utilize the above metals for their favorable properties and at the same time the metals can be protected from corrosion. Furthermore, the covers can have an attractive appearance. In some cases, it can be desirable to chamfer certain edges of the cover for ergonomics and/or to enhance the appearance of the cover. Some examples of edges that may be chamfered can include an edge surrounding a track pad on a lap top, an edge surrounding a fingerprint scanner, an outer edge of a smartphone housing, and so on. The covers described herein can include a chamfered edge that can have a customized appearance such as a metallic luster appearance, a colored metallic luster appearance, or an opaque colored appearance.

In certain examples, the cover can have a first protective coating such as a MAO layer or a passivation layer and a second protective coating such as a paint coating. The chamfer can cut through the first protective coating and the second protective coating to expose the metal of the cover substrate below. The chamfer may also cut through a portion of the metal of the cover substrate. The chamfer may be accomplished using computer numeric control (CNC) or laser engraving. After the metal is exposed at the chamfered edge, the metal can be treated with a transparent passivation treatment to form a transparent passivation layer at the exposed metal. After this, an electrophoretic deposition layer may be deposited over the chamfered edge. The paint coating may include more than one layer. For example, the paint coating may include one, two, three, or four layers. The paint coating may include a primer coat, a base coat, and a top coat. A primer coat may include a polyester, a polyurethane, or a copolymer thereof. The base coat may include a polyester, a polyurethane, or a copolymer thereof. The top coat may include a polyurethane, a polyacrylic or polyacrylate, a urethane, an epoxy, or a copolymer thereof.

It is appreciated that chemicals used for the passivation layer for the first protective coating may be different than chemicals used for the transparent passivation layer. For example, the passivation layer for the first protective coating may be opaque and may include molybdates, vanadates, phosphates, chromates, stannates, manganese salts, or a combination thereof. The passivation layer may be 1-5 μm thick. Chemicals for the transparent passivation layer may contain chelating agents including ethylenediaminetetraacetic acid (EDTA), ethylenediamine, nitrilotriacetic acid (NTA), diethylenetriaminepenta (methylenephosphonic acid) (DTPPH), and nitrilotris (methylenephosphonic acid) (NTMP), 1-hydroxyethane-1,1-diphosphonic acid (HEDP), phosphoric acid, and organic acid in combination with aluminum, nickel, chromium, tin, indium, and zinc ions in the formulation. The transparent passivation layer may be 30 nm-3 μm thick.

In various examples, resultant protection can be transparent, semi-transparent, or opaque. Different colors may be used at different edges of the cover. The different colors may be introduced by employing different colorants, such as dyes or pigments, in the electrophoretic deposition layer on one chamfered edge as compared to another. Thus, the chamfered edge can have a natural metallic luster appearance, a colored metallic appearance, or an opaque colored appearance depending on the type of ink printed onto the chamfered edge. The color of the chamfered edge can be customized and in some cases the color of the chamfered edge can be selected to contrast with or compliment the color of the protective coating on the cover substrate.

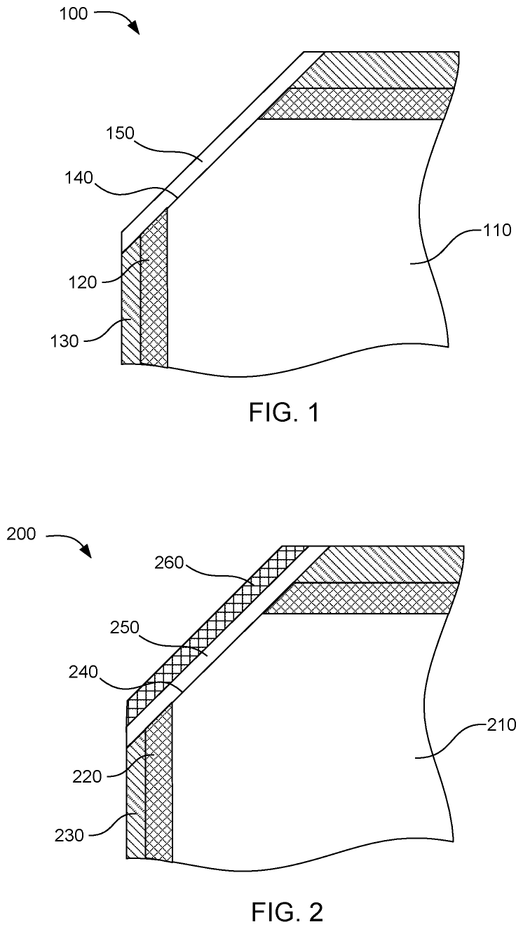

FIG. 1 shows an example cover 100 for an electronic device. The cover 100 includes a light metal substrate 110 with a first protective coating 120 on a surface of the light metal substrate 110. The cover 100 also includes a second protective coating 130 over the first protective coating 120. An edge 140 of the cover 100 is chamfered, whereby the chamfer cuts through the first protective coating 120, the second protective coating 130, and a portion of the light metal substrate 110 to expose a portion of the light metal substrate 110. The exposed portion of the light metal substrate 110 may be referred to as a chamfered edge 140. A transparent passivation layer 150 is formed at the exposed light metal substrate 110 at the chamfered edge 140.

As shown in FIG. 1, in this example an edge of the cover 100 is chamfered by cutting away material along a 90° angled edge at about a 45° angle so that the 90° edge is replaced by a sloped surface at about 45°. Accordingly, as used herein, “chamfer” refers to the action of cutting away an edge where two faces meet to form a sloping face transitioning between the two original faces. In some cases, the term “chamfered edge” can refer to the entire transition area between the original faces and the metal at the edge before chamfering together with the sloped face created by the chamfering. In other cases, the term “chamfered edge” may refer specifically to the sloped face created by the chamfering. In many cases, the original edge can be a 90° angle edge, and the chamfer can create a sloping face at a 45° angle. However, in some examples the original edge can have a different angle and the chamfer can create a sloping surface with a different angle. The chamfer can be performed using CNC techniques or laser engraving. In further examples, chamfering can be performed using a milling machine with a cutting bit oriented to cut away the edge and create the sloped surface of the chamfered edge. In other examples, the chamfer can be performed by laser cutting, water jet cutting, sanding, or any other suitable method.

As mentioned above, in some examples the light metal substrate can be treated by micro-arc oxidation as part of the first protective coating 120. The micro-arc oxidation treatment can be performed before the light metal substrate is coated with the second protective coating 130. Alternatively, the light metal substrate can be treated by a passivation technique to form the first protective coating 120. The second protective coating 130 may be a paint coating as described above, with any number of layers of paint.

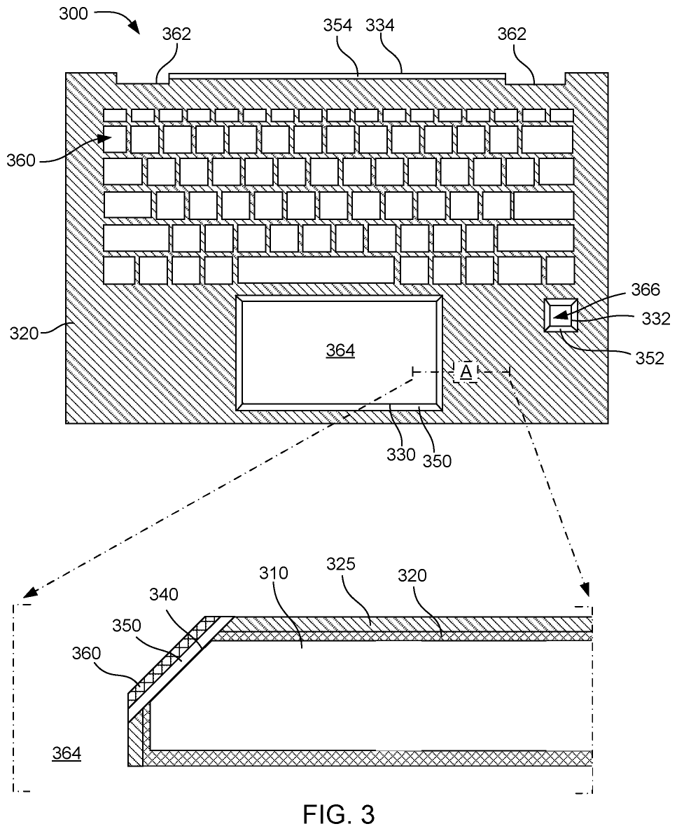

FIG. 2 shows an example cover 200 for an electronic device in which the light metal substrate 210 is coated with a first protective coating 220 and a second protective coating 230. A chamfered edge 240 is then formed, which cuts through both the first protective coating 220 and the second protective coating 230. A transparent passivation layer 250 is formed at the exposed metal of the light metal substrate 210 at the chamfered edge 240. An electrophoretic deposition layer 260 is then deposited over the transparent passivation layer 250.

Depending on the shape and design of a cover for an electronic device, the cover may have many different edges. Any of these edges can be chamfered depending on the desired final appearance of the cover. More particularly, in some examples the light metal substrate (including either the entire substrate, a portion of the substrate, or multiples portions of the substrate) can be coated with the first protective coating and the second protective coating. Then any edge or multiple edges can be chamfered such that the chamfer cuts through the first and second protective coatings and exposes the light metal substrate. The chamfered edges can be treated with a passivation treatment to form a transparent passivation layer at the exposed light metal substrate of the chamfered edge. In a further example, an electrophoretic deposition layer can be deposited over the transparent passivation layer. The resulting chamfered edges may be multi colored such that one chamfered edge of the cover may be a different color than another chamfered edge of the cover.

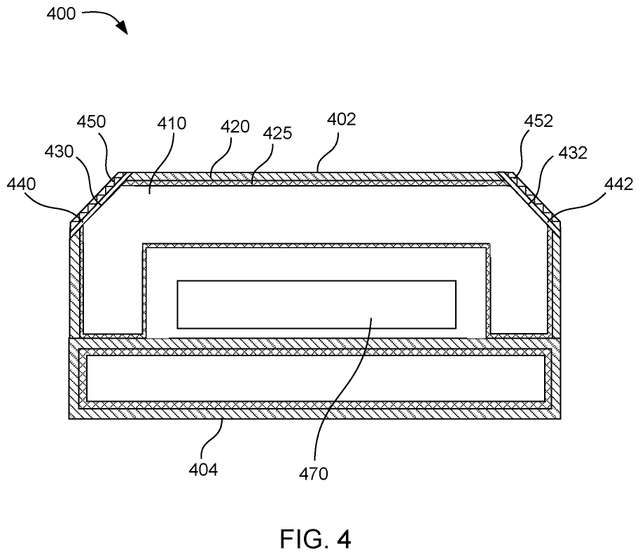

FIG. 3 shows another example cover 300 for an electronic device. This example is a top cover for the keyboard portion of a laptop (sometimes referred to as a “laptop cover C”). The cover includes key openings 360 for the keyboard buttons (not shown) to be positioned therethrough, hinge recesses 362 to receive a hinge (not shown), a track pad opening 364 to receive a track pad (not shown), and a fingerprint scanner opening 366 to receive a fingerprint scanner (not shown). These are merely examples of structures that may be present, and are illustrative of many of a number of other structural components used with this type of top cover. The cover is mostly made up of a light metal substrate 310 coated with a first protective coating 320 and a second protective coating 325. The light metal substrate 310 is not directly visible in this example because it is covered by the protective coating. In this example, chamfered edges have been formed at three different locations: a track pad chamfered edge 330 surrounding the track pad opening, a fingerprint scanner chamfered edge 332 surrounding the fingerprint scanner opening, and a rear chamfered edge 334 along the rear edge of the cover near the hinge. Each of these chamfered edges is treated with a passivation treatment to form transparent passivation layers represented by transparent passivation layer 350. The transparent passivation layer 350 is then covered by an electrophoretic deposition layer 360. Pigments or dyes in the electrophoretic deposition layer 360 may be used to introduce a color over the chamfered edge. For example, the track pad chamfered edge 330, the fingerprint scanner chamfered edge 332, and the rear chamfered edge 334 may each be different colors from one another or may be the same color. Alternatively, the electrophoretic deposition layer 360 may be transparent such that the light metal substrate 310 is visible and protected.

To show the various materials in this example more clearly, a partial cross-sectional view is shown along plane “A” designated further by the dashed and dotted lines/arrows. This cross-sectional view shows the chamfered edge 340 bordering the track pad opening 364. The chamfer cuts through the first protective coating 320 and the second protective coating 325 as well as a portion of the light metal substrate 310. The transparent passivation layer 350 is formed at the exposed light metal substrate. The electrophoretic deposition layer 360 is then deposited to cover the transparent passivation layer 350. As shown in the figure, in this example the chamfered edge includes a sloping face that slopes downward toward the track pad opening. When the cover is assembled with other components to make a complete laptop, this chamfered edge can provide a more comfortable edge around the track pad compared to a sharp 90° edge. Similarly, the chamfered edge around the fingerprint scanner can slop downward toward the fingerprint scanner in some examples.

As used herein, “cover” refers to the exterior shell of an electronic device that includes or is in the form of an enclosure, and a portion thereof (or the structure thereof) includes a light metal substrate. In other words, the cover can be adapted to contain the internal electronic components of the electronic device. The cover can be an integral part of the electronic device. The term “cover” is not meant to refer to the type of removable protective cases that are often purchased separately for an electronic device (especially smartphones and tablets) and placed around the exterior of the electronic device. Covers as described herein can be used on a variety of electronic devices. For example, a laptop, a desktop, a keyboard, a mouse, a printer, a smartphone, a tablet, a monitor, a television, a speaker, a game console, a video player, an audio player, or a combination thereof. In various examples, the light metal substrate for these covers can be formed by molding, casting, machining, bending, working, stamping, or another process. In one example, a light metal substrate can be milled from a single block of metal. In other examples, the cover can be made from multiple panels. For example, laptop covers sometimes include four separate cover pieces forming the complete cover of the laptop. The four separate pieces of the laptop cover are often designated as cover A (back cover of the monitor portion of the laptop), cover B (front cover of the monitor portion), cover C (top cover of the keyboard portion) and cover D (bottom cover of the keyboard portion). Covers can also be made for smartphones and tablet computers with a single metal piece or multiple metal panels.

As used herein, a layer that is referred to as being “on” a lower layer can be directly applied to the lower layer, or an intervening layer or multiple intervening layers can be located between the layer and the lower layer. Generally, the covers described herein can include a light metal substrate and a protective coating can be applied on the light metal substrate. Accordingly, a layer that is “on” a lower layer can be located further from the light metal substrate. However, in some examples there may be other intervening layers such as a primer layer underneath the protective layer. Furthermore, the protective layer itself may include multiple layers, such as a base layer, a topcoat layer, and any other intervening layers. In some examples, the protective coating and any other layers may be applied to an exterior surface of the light metal substrate. Thus, a “higher” layer applied “on” a “lower” layer may be located farther from the light metal substrate and closer to a viewer viewing the cover from the outside. In further examples, the protective coating can be applied to all surfaces of the light metal substrate.

It is noted that when discussing covers for electronic devices, the electronic devices themselves, or methods of making covers for electronic devices, such discussions can be considered applicable to one another whether or not they are explicitly discussed in the context of that example. Thus, for example, when discussing the metals used in the light metal substrate in the context of one of the example covers, such disclosure is also relevant to and directly supported in the context of the electronic devices and/or methods, and vice versa. It is also understood that terms used herein will take on their ordinary meaning in the relevant technical field unless specified otherwise. In some instances, there are terms defined more specifically throughout or included at the end of the present disclosure, and thus, these terms are supplemented as having a meaning described herein.

### Electronic Devices

A variety of electronic devices can be made with the covers described herein. In various examples, such electronic devices can include various electronic components enclosed by the cover. As used herein, “encloses” or “enclosed” when used with respect to the covers enclosing electronic components can include covers completely enclosing the electronic components or partially enclosing the electronic components. Many electronic devices include openings for charging ports, input/output ports, headphone ports, and so on. Accordingly, in some examples the cover can include openings for these purposes. Certain electronic components may be designed to be exposed through an opening in the cover, such as display screens, keyboard keys, buttons, track pads, fingerprint scanners, cameras, and so on. Accordingly, the covers described herein can include openings for these components. Other electronic components may be designed to be completely enclosed, such as motherboards, batteries, sim cards, wireless transceivers, memory storage drives, and so on. Additionally, in some examples a cover can be made up of two or more cover sections, and the cover sections can be assembled together with the electronic components to enclose the electronic components. As used herein, the term “cover” can refer to an individual cover section or panel, or collectively to the cover sections or panels that can be assembled together with electronic components to make the complete electronic device.

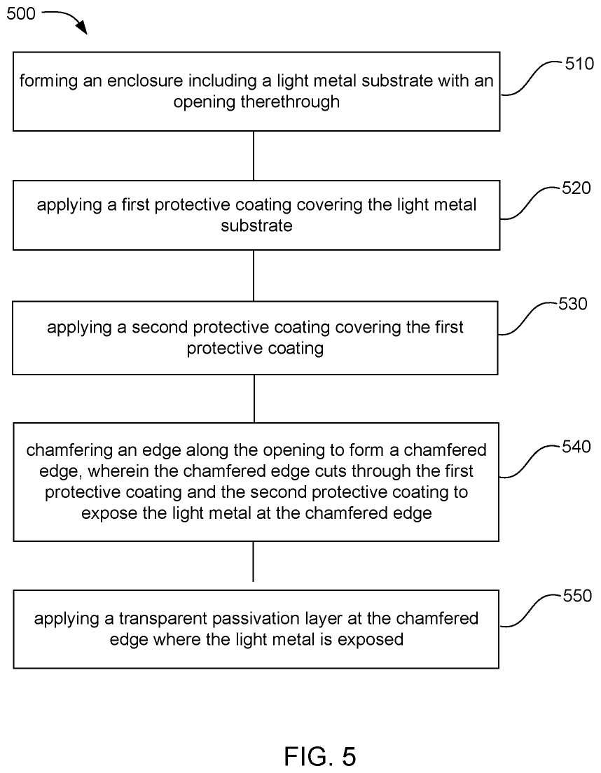

FIG. 4 shows a cross-sectional schematic view of an example electronic device 400 in accordance with examples of the present disclosure. This example includes a top cover 402 and a bottom cover 404 enclosing an electronic component 470. The top cover includes a light metal substrate 410 with a first protective coating 420 and a second protective coating 425. Two chamfered edges 430, 432 are formed by chamfers that cut through the first and second protective coatings and expose the light metal substrate. Transparent passivation layers 440, 442 are formed at the exposed light metal substrate at the chamfered edges and electrophoretic deposition layers 450, 452 are printed over the transparent passivation layers 440, 442 and the chamfered edges.

In further examples, the electronic device can be a laptop, a desktop, a keyboard, a mouse, a printer, a smartphone, a tablet, a monitor, a television, a speaker, a game console, a video player, an audio player, or a variety of other types of electronic devices. In certain examples, the chamfered edge or edges can be located in decorative locations on the cover. Some examples include chamfered edges around track pads, around fingerprint scanners, around an edge of a logo, and so on. In further detail, there may be outer periphery of the light metal substrate that can be similarly chamfered.

### Methods of Making Covers for Electronic Devices

In some examples, the covers described herein can be made by first forming the light metal substrate. This can be accomplished using a variety of processes, including molding, insert molding, forging, casting, machining, stamping, bending, working, and so on. The light metal substrate can be made from a variety of metals. In one example, sheet or forge metal is insert molded into the shape of a cover. In certain examples, the light metal substrate can include aluminum, magnesium, lithium, titanium, zinc, or an alloy thereof. As mentioned above, in some examples the light metal substrate can be a single piece while in other examples the light metal substrate can include multiple pieces that each make up a portion of the cover. Additionally, in some examples the light metal substrate can be a composite made up of multiple metals combined, such as having layers of multiple different metals or panels or other portions of the light metal substrate being different metals.

A first protective coating can be applied to a surface of the light metal substrate. In some examples, the protective coating can be applied to any surface of the light metal substrate, including fully or partially covering a single surface, fully or partially covering multiple surfaces, or fully or partially covering the light metal substrate as a whole. The protective coating can be applied by any suitable application method. In one example, the first protective coating can be a micro-arc oxidation layer. In one example, the first protective coating can be an opaque passivation layer.

A second protective coating can be applied to the surface of the first protective coating. In one example, the second protective coating is a paint coating. The paint coating may have any number of layers. For example, the paint coating may include a primer coat, a base coat and a top coat.

The chamfered edges can be formed on an edge of the light metal substrate coated with the first and second protective coatings. In various examples, chamfered edges can be formed at any edge or combination of edges on the cover. The chamfered edge can vary in depth. The term “depth” of chamfered edges refers to the amount of the edge that is cut away by the chamfering process. The depth of the chamfer can be stated in terms of the distance from the original edge of the cover to the edge of the sloped surface created by the chamfering. In various examples, the chamfer can be from about 0.1 mm to about 1 cm deep. In other examples, the chamfer can be from about 0.2 mm to about 5 mm deep. As stated above, in some examples the chamfer can be symmetrical so that the same amount of material is removed on both faces of the cover that meet at the chamfered edge. In a symmetrical chamfering of a 90° edge, the new sloped surface created by the chamfering is at a 45° angle with respect to the original faces of the cover. However, in other examples, the chamfer can be asymmetrical so that the angle of the sloped surface is different with respect to each of the original faces of the cover. The examples of the depth of the chamfer described above can refer to either side of the chamfer in the case of an asymmetrical chamfer.

The chamfered edge can be formed using any suitable process that can remove material at the edge of the cover and produce a sloped surface in place of the original edge. In some examples, the chamfer can be formed using a CNC machine such as a milling machine, a router, a laser engraver, a laser cutter, a water jet cutter, a sander, a file, or other methods.

A transparent passivation layer can be formed on the exposed light metal substrate after chamfering the edge. In some examples, this can be accomplished using a passivation treatment. Some passivation treatments may include immersing the cover in a passivation treatment bath, so that all surfaces of the cover are contacted by reagents for the passivation treatment. However, in some examples the passivation treatment may affect the exposed light metal substrate while having no effect on the surfaces that are coated with the protective coating. Transparent passivation treatments can include treatments involving a chelating agent and a metal ion or a chelated metal complex, as described in more detail below.

The transparent passivation layer can be covered with an electrophoretic deposition layer. The electrophoretic deposition layer can be deposited and can include a polymeric binder, a pigment, and a dispersant. The electrophoretic deposition layer can include transparent, semi-transparent, and opaque finishes of any desired color as described in more detail below. In certain examples, multiple different colors can be deposited over multiple different chamfered edges of the cover.

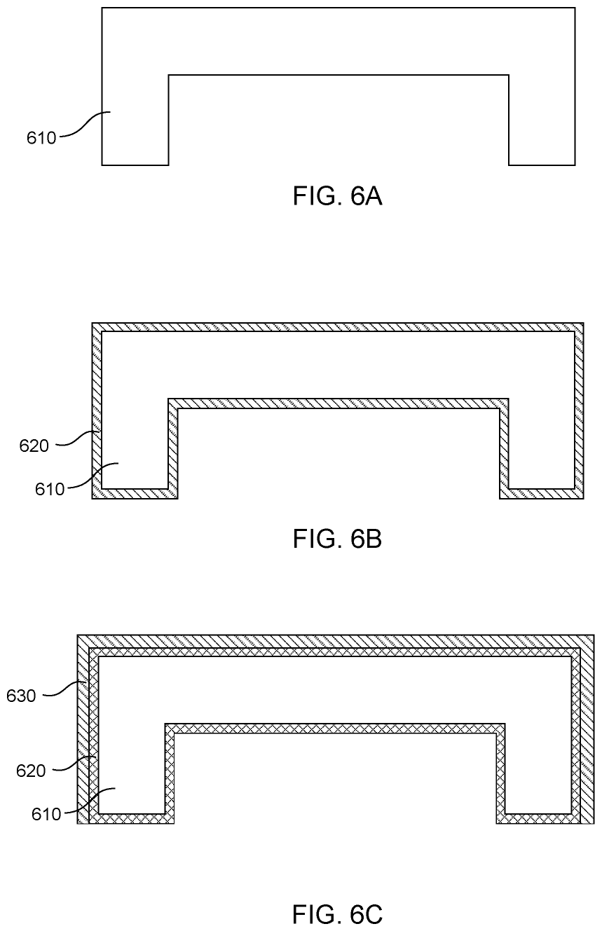

FIG. 5 is a flowchart illustrating an example method 500 of making a cover for an electronic device. The method includes forming 510 an enclosure including a light metal substrate with an opening therethrough, applying 520 a first protective coating covering the light metal substrate, and applying 530 a second protective coating covering the first protective coating. The method further includes chamfering 540 an edge along the opening to form a chamfered edge, wherein the chamfered edge cuts through the first protective coating and the second protective coating to expose the light metal at the chamfered edge, and furthermore, applying 550 a transparent passivation layer at the chamfered edge where the light metal is exposed.

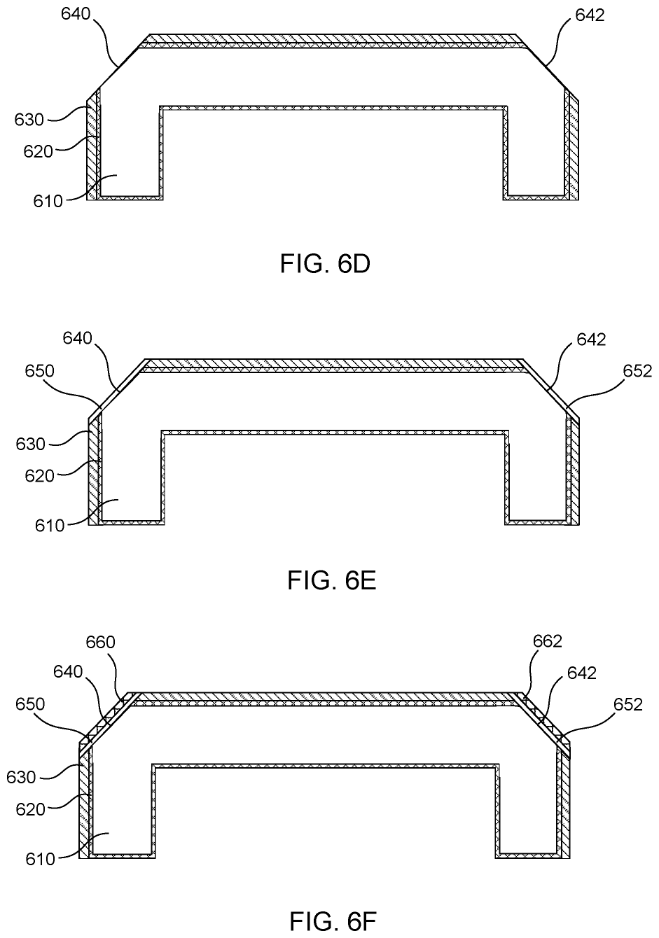

FIGS. 6A-6F show cross-sectional views illustrating another example method of making a cover for an electronic device. In FIG. 6A, a light metal substrate 610 is formed. In FIG. 6B, the light metal substrate 610 is coated with a first protective coating 620. In FIG. 6C, the first protective coating 620 is coated with a second protective coating 630. In FIG. 6D, two edges of the light metal substrate 610 are chamfered to form chamfered edges 640, 642. The chamfers cut through the first protective coating 620 and the second protective coating 630 and a portion of the light metal substrate 610 and expose a surface of the light metal substrate. After chamfering the edges, transparent passivation layers 650, 652 are formed at the exposed light metal substrate 610 as shown in FIG. 6E. Finally, FIG. 6F shows electrophoretic deposition layers 660, 662 deposited over the chamfered edges.

### Light Metal Substrates for Electronic Device Covers

The light metal substrate can be made from a single metal, a metallic alloy, a combination of sections made from multiple metals, or a combination of metal and other materials. In certain examples, the light metal substrate can include aluminum, magnesium, lithium, titanium, zinc, or an alloy thereof. In further particular examples, the light metal substrate can include aluminum, an aluminum alloy, magnesium, or a magnesium alloy. Non-limiting examples of elements that can be included in aluminum or magnesium alloys can include aluminum, magnesium, titanium, lithium, niobium, zinc, bismuth, copper, cadmium, iron, thorium, strontium, zirconium, manganese, nickel, lead, silver, chromium, silicon, tin, gadolinium, yttrium, calcium, antimony, cerium, lanthanum, or others.

In some examples, the light metal substrate can include an aluminum magnesium alloy made up of about 0.5% to about 13% magnesium by weight and 87% to 99.5% aluminum by weight. Examples of specific aluminum magnesium alloys can include 1050, 1060, 1199, 2014, 2024, 2219, 3004, 4041, 5005, 5010, 5019, 5024, 5026, 5050, 5052, 5056, 5059, 5083, 5086, 5154, 5182, 5252, 5254, 5356, 5454, 5456, 5457, 5557, 5652, 5657, 5754, 6005, 6005A, 6060, 6061, 6063, 6066, 6070, 6082, 6105, 6162, 6262, 6351, 6463, 7005, 7022, 7068, 7072, 7075 ,7079, 7116, 7129, and 7178.

In further examples, the light metal substrate can include magnesium metal, a magnesium alloy that is 99% or more magnesium by weight, or a magnesium alloy that is from about 50% to about 99% magnesium by weight. In a particular example, the light metal substrate can include an alloy including magnesium and aluminum. Examples of magnesium-aluminum alloys can include alloys made up of from about 91% to about 99% magnesium by weight and from about 1% to about 9% aluminum by weight, and alloys made up of about 0.5% to about 13% magnesium by weight and 87% to 99.5% aluminum by weight. Specific examples of magnesium-aluminum alloys can include AZ63, AZ81, AZ91, AM50, AM60, AZ31, AZ61, AZ80, AE44, AJ62A, ALZ391, AMCa602, LZ91, and Magnox.

The light metal substrate can be shaped to fit any type of electronic device, including the specific types of electronic devices described herein. In some examples, the light metal substrate can have any thickness suitable for a particular type of electronic device. The thickness of the metal in the light metal substrate can be selected to provide a desired level of strength and weight for the cover of the electronic device. In some examples, the light metal substrate can have a thickness from about 0.5 mm to about 2 cm, from about 1 mm to about 1.5 cm, from about 1.5 mm to about 1.5 cm, from about 2 mm to about 1 cm, from about 3 mm to about 1 cm, from about 4 mm to about 1 cm, or from about 1 mm to about 5 mm, though thicknesses outside of these ranges can be used.

### First Protective Coatings for Electronic Device Covers

In one example, a first protective coating is applied to the light metal substrate and is a micro-arc oxidation layer on a surface thereof. Micro-arc oxidation, also known as plasma electrolytic oxidation, is an electrochemical process where the surface of a metal is oxidized using micro-discharges of compounds on the surface of the substrate when immersed in a chemical or electrolytic bath, for example. The electrolytic bath may include predominantly water with about 1 wt % to about 5 wt % electrolytic compound(s), e.g., alkali metal silicates, alkali metal hydroxide, alkali metal fluorides, alkali metal phosphates, alkali metal aluminates, the like, and combinations thereof. The electrolytic compounds may likewise be included at from about 1.5 wt % to about 3.5 wt %, or from about 2 wt % to about 3 wt %, though these ranges are not considered limiting. In one example, a high-voltage alternating current can be applied to the substrate to create plasma on the surface of the substrate. In this process, the substrate can act as one electrode immersed in the electrolyte solution, and the counter electrode can be any other electrode that is also in contact with the electrolyte. In some examples, the counter electrode can be an inert metal such as stainless steel. In certain examples, the bath holding the electrolyte solution can be conductive and the bath itself can be used as the counter electrode. A high direct current or alternating voltage can be applied to the substrate and the counter electrode. In some examples, the voltage can be about 200 V or higher, such as about 200 V to about 600 V, about 250 V to about 600 V, about 250 V to about 500 V, or about 200 V to about 300 V. Temperatures can be from about 20° C. to about 40° C., or from about 25° C. to about 35° C., for example, though temperatures outside of these ranges can be used. This process can oxidize the surface to form an oxide layer from the substrate material. Various metal or metal alloy substrates can be used, including aluminium, titanium, lithium, magnesium, and/or alloys thereof, for example. The oxidation can extend below the surface to form thick layers, as thick as 30 μm or more. In some examples the oxide layer can have a thickness from about 1 μm to about 25 μm, from about 1 μm to about 22 μm, or from about 2 μm to about 20 μm. Thickness can likewise be from about 2 μm to about 15 μm, from about 3 μm to about 10 μm, or from about 4 μm to about 7 μm. The oxide layer can, in some instances, enhance the mechanical, wear, thermal, dielectric, and corrosion properties of the substrate. The electrolyte solution can include a variety of electrolytes, such as a solution of potassium hydroxide. In some examples, the light metal substrate can include a micro-arc oxidation layer on one side, or on both sides.

In an alternative example, the first protective coating is an opaque passivation layer. The passivation layer may refer to a layer or coating over the light metal substrate. Passivation may refer to the use of a light coat of a protective material, such as metal oxide, to create a shell against corrosion. Chemicals may be applied to the surface of the light metal substrate to induce the passivation layer. For example, the chemicals may include at least one of molybdates, vanadates, phosphates, chromates, stannates and manganese salts. The passivation layer may have a thickness of 1-5 μm.

### Second Protective Coatings for Electronic Device Covers

In some examples, a second protective coating is applied over the first protective coating. For example, the second protective coating may be a paint coating. The paint coating may include one, two, three or four layers or any other number of layers. The paint coating may include a primer coat, a base coat, and/or a top coat. The paint coating may be applied using any number of techniques including spray painting or inkjet painting. The paint may be composed of a variety of materials. In one example, a primer coat can include a polyester, a polyurethane, or a copolymer thereof. In one example, a base coat can include a polyester, a polyurethane, or a copolymer thereof. In one example, a top coat can include a polyurethane, a polyacrylic or polyacrylate, a urethane, an epoxy, or a copolymer thereof. The paint coating can be any number of colors and can be transparent, semi-transparent, or opaque.

### Transparent Passivation Layers for Electronic Device Covers

In further examples, a passivation treatment can be used to form a transparent passivation layer at the light metal substrate exposed at the chamfered edge. It is noted that the transparent passivation layer is described as a layer for convenience, and thus, can be in the form of a layer. However, the term “passivation layer” also includes metal surface treatment of the exposed metal substrate. In some sense, it may not be a discrete layer that is applied similarly to that of a coating or a paint, for example, but can become infused or otherwise become part of the metal substrate at or near a surface of the chamfered edge. In some examples, the transparent passivation layer can include a chelating agent and a metal ion or a chelated metal complex thereof, wherein the metal ion is an aluminum ion, an indium ion, a nickel ion, a chromium ion, a tin ion, or a zinc ion. In certain examples, passivation treatment can be applied at a pH from about 2 to about 6. In a particular example, the pH can be about 2.5 to about 3.5. In further examples, the transparent passivation layer can include an oxide of one of these metals. In some cases, various contaminants can be present on the surface of the light metal substrate. The chelating agent can chelate such contaminants and prevent the contaminants from attaching to the surface of the light metal substrate. Non-limiting examples of chelating agents can include ethylenediaminetetraacetic acid, ethylenediamine, nitrilotriacetic acid, diethylenetriaminepenta (methylenephosphonic acid), nitrilotris (methylenephosphonic acid) and 1-hydroxyethane-1,1-disphosphonic acid. At the same time, a passivating metal oxide layer may form on the surface of the light metal substrate. In some examples, the transparent passivation layer can have a thickness from about 30 nm to about 3 μm. In certain examples, the transparent passivation layer can be added to the pre-existing surface of the light metal substrate, such that the transparent passivation layer includes additional material added onto the surface of the light metal substrate. In other examples, the passivation layer can involve converting the existing surface of the light metal substrate into a passive layer so that no net addition of material to the pre-existing surface occurs.

### Electrophoretic Deposition Layers for Electronic Device Covers

In other examples the transparent passivation layer can be covered with an electrophoretic deposition layer. The electrophoretic deposition layer or coating can include a polymeric binder, a pigment, and a dispersant. The electrophoretic coating process can sometimes be referred to as “electropainting” or “electrocoating” because of the use of electric current in the process. To deposit an electrophoretic coating on the cover of the electronic device, the light metal substrate can be placed in a coating bath. The coating bath can include a suspension of particles including the polymeric binder, pigment, and dispersant. In certain examples, the solid content of the coating bath can be from about 3 wt % to about 30 wt % or from about 5 wt % to about 15 wt %. The light metal substrate can be electrically connected to an electric power source. The light metal substrate can act as one electrode and the power source can also be attached to a second electrode that is also in contact with the coating bath. An electric current can be run between the light metal substrate and the second electrode. In certain examples, the electric current can be applied at a voltage from about 30 V to about 150 V. The electric current can cause the particles suspended in the coating bath to migrate to the surface of the light metal substrate and coat the surface. After this deposition process, additional processing may be performed such as rinsing the light metal substrate, baking the coated substrate to harden the coating, or exposing the coated substrate to radiation to cure radiation curable polymeric binders.

In some examples, electrophoretic coatings can include the same pigments and polymeric binders or resins described above in the paint-type protective coating. The thickness of the coating can also be in the same ranges described above. Different colors can be applied to different chamfered edges of the light metal substrate.

### DEFINITIONS

It is noted that, as used in this specification and the appended claims, the singular forms “a,” “an,” and “the” include plural referents unless the content clearly dictates otherwise.

The term “about” as used herein, when referring to a numerical value or range, allows for a degree of variability in the value or range, for example, within 5% or other reasonable added range breadth of a stated value or of a stated limit of a range. The term “about” when modifying a numerical range is also understood to include the exact numerical value indicated, e.g., the range of about 1 wt % to about 5 wt % includes 1 wt % to 5 wt % as an explicitly supported sub-range.

As used herein, “colorant” can include dyes and/or pigments.

As used herein, “dye” refers to compounds or molecules that absorb electromagnetic radiation or certain wavelengths thereof. Dyes can impart a visible color to an ink if the dyes absorb wavelengths in the visible spectrum.

As used herein, “pigment” generally includes pigment colorants, magnetic particles, aluminas, silicas, and/or other ceramics, organo-metallics or other opaque particles, whether or not such particulates impart color. Thus, though the present description primarily exemplifies the use of pigment colorants, the term “pigment” can be used more generally to describe pigment colorants and other pigments such as organometallics, ferrites, ceramics, etc. In one specific example, however, the pigment is a pigment colorant.

As used herein, a plurality of items, structural elements, compositional elements, and/or materials may be presented in a common list for convenience. However, these lists should be construed as though the individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, and also to include all the individual numerical values or sub-ranges encompassed within that range as if individual numerical values and sub-ranges are explicitly recited. For example, a layer thickness from about 0.1 μm to about 0.5 μm should be interpreted to include the explicitly recited limits of 0.1 μm to 0.5 μm, and to include thicknesses such as about 0.1 μm and about 0.5 μm, as well as subranges such as about 0.2 μm to about 0.4 μm, about 0.2 μm to about 0.5 μm, about 0.1 μm to about 0.4 μm etc.

The following illustrates an example of the present disclosure. However, it is to be understood that the following is illustrative of the application of the principles of the present disclosure. Numerous modifications and alternative compositions, methods, and systems may be devised without departing from the spirit and scope of the present disclosure. The appended claims are intended to cover such modifications and arrangements.

### EXAMPLE

An example cover for an electronic device is made as follows:

1) A light metal substrate is made by molding magnesium alloy in the form of a laptop cover with a “C” shape and/or as a keyboard surface with openings therein for keys, a track pad, and/or a fingerprint pad.
2) The light metal substrate is subjected to micro-arc oxidation to form a protective coating on the light metal substrate.
3) The light metal substrate with the micro-arc oxidation layer is painted using multiple coats of spray paint.
4) A CNC milling machine is used to cut a first chamfer along the edges of the opening for the track pad. A second chamfer is cut along the edges of the opening for the fingerprint scanner. A third chamfer is cut along the rear edge of the light metal substrate (outer periphery). The chamfers are cut at about a 45° angle and have a depth of about 2 mm from the corner of the corner (now chamfered and no longer present) along the edge.
5) The chamfered light metal substrate is placed in a passivation bath including ethylenediaminetetraacetic acid as a chelating agent and zinc ions at a pH of 3.5 to form transparent passivation layers at the exposed metal at the chamfered edges.
6) An electrophoretic deposition process is used to deposit a protective colored layer over the chamfered edge.

What is claimed is:

1. A cover for an electronic device comprising:
an enclosure with a light metal substrate having an opening therethrough;
a first protective coating covering the light metal substrate;
a second protective coating covering the first protective coating;
a chamfered edge along the opening, wherein the chamfered edge cuts through the first protective coating and the second protective coating to expose the light metal substrate at the chamfered edge; and
a transparent passivation layer on the light metal substrate along the chamfered edge.

2. The cover of claim 1, wherein the light metal substrate is a magnesium alloy that is formed from sheet or forge magnesium alloy using insert molding.

3. The cover of claim 1, wherein the first protective coating is an opaque passivation layer including molybdates, vanadates, phosphates, chromates, stannates, manganese salts, or a combination thereof.

4. The cover of claim 1, wherein the first protective coating is a micro-arc oxidation layer.

5. The cover of claim 1, wherein the second protective coating is a multilayered coating comprising:
a primer coat including a polyester, a polyurethane, or a copolymer thereof; and
one or both of a base coat or a top coat, the base coat if present including a polyester, a polyurethane, or a copolymer thereof, and the top coat if present including a polyurethane, a polyacrylic or polyacrylate, a urethane, an epoxy, or a copolymer thereof.

6. The cover of claim 1, wherein the chamfered edge is formed using a computer numerical control (CNC) mill or laser engraving.

7. The cover of claim 1, wherein the transparent passivation layer comprises a pretreatment chemical that includes ethylenediaminetetraacetic acid, ethylenediamine, nitrilotriacetic acid, diethylenetriaminepenta, nitrilotris, hydroxyethane, diphosphonic acid, phosphoric acid, organic acid, or a combination thereof.

8. The cover of claim 1, further comprising a second chamfered edge with a second transparent passivation layer.

9. The cover of claim 1, further comprising an electrophoretic deposition layer covering the transparent passivation layer over the chamfered edge to form a colored layer.

10. An electronic device comprising:
an electronic component; and
a cover enclosing the electronic component, the cover comprising:
an enclosure including a light metal substrate having an opening therethrough,
a first protective coating covering the light metal substrate,
a second protective coating covering the first protective coating,
a chamfered edge along the opening, wherein the chamfered edge cuts through the first protective coating and the second protective coating to expose the light metal substrate at the chamfered edge, and
a transparent passivation layer on the light metal substrate along the chamfered edge.

11. The electronic device of claim 10, wherein the electronic device is a laptop, tablet computer, smartphone, an e-reader, or a music player.

12. The electronic device of claim 10, wherein the chamfered edge is located at an edge of a touch pad, an edge of a fingerprint scanner, an outer edge of the cover, an edge of a sidewall, or an edge of a logo.

13. The electronic device of claim 10, wherein the cover comprises multiple chamfered edges with multiple colors at different chamfered edges.

14. A method of making a cover for an electronic device comprising:
forming an enclosure including a light metal substrate with an opening therethrough;
applying a first protective coating covering the light metal substrate;
applying a second protective coating covering the first protective coating;
chamfering an edge along the opening to form a chamfered edge, wherein the chamfered edge cuts through the first protective coating and the second protective coating to expose the light metal at the chamfered edge; and
applying a transparent passivation layer at the chamfered edge where the light metal is exposed.

15. The method of claim 14, further comprising applying an electrophoretic deposition layer covering the transparent passivation layer over the chamfered edge.
